(19) United States
(12) Patent Application Publication
(10) Pub. No.: US 2026/0334280 A1
(43) Pub. Date: Oct. 22, 2026

(54) SEMICONDUCTOR STRUCTURE WITH BONDING-ENHANCEMENT PADS

(71) Applicant: UNITED MICROELECTRONICS CORP., Hsin-Chu City (TW)

(72) Inventors: Yao-Hsien Chung, Tainan City (TW); Fu-Yu Tsai, Tainan City (TW); Bin-Siang Tsai, Changhua County (TW)

(73) Assignee: UNITED MICROELECTRONICS CORP., Hsin-Chu City (TW)

(21) Appl. No.: 19/720,824

(22) Filed: Jun. 25, 2026

Related U.S. Application Data
(63) Continuation of application No. 18/419,583, filed on Jan. 23, 2024, now Pat. No. 12,721,210.

(30) Foreign Application Priority Data
Dec. 20, 2023 (TW) 112149771

(51) Int. Cl. H10W 72/90; H10W 72/00; H10W 70/63

(52) U.S. Cl. CPC H10W 72/90; H10W 72/019; H10W 70/635; H10W 72/923; H10W 72/926; H10W 72/952; H10W 72/957

(57) ABSTRACT

A semiconductor structure includes a semiconductor substrate, a dielectric structure disposed on the semiconductor substrate, a plurality of conductive pads, and a plurality of bonding-enhancement pads. The plurality of conductive pads is disposed in the dielectric structure. Top surfaces of the plurality of conductive pads and a top surface of the dielectric structure collectively form a bonding interface. The plurality of bonding-enhancement pads is disposed in the dielectric structure and exposed at the bonding interface. A material of the plurality of bonding-enhancement pads is different from a material of the dielectric structure and a material of the conductive pads. The material of the bonding-enhancement pads includes a silicon-rich material to provide a plurality of dangling bonds at the bonding interface, thereby enhancing local wafer bonding strength and preventing edge bonding voids.

### CROSS REFERENCE TO RELATED APPLICATIONS

This application is a continuation application of U.S. Application No. 18/419,583, filed on Jan. 23rd, 2024. The content of the application is incorporated herein by reference.

### BACKGROUND OF THE INVENTION

### 1. Field of the Invention

The present disclosure relates to the field of semiconductor technology, and in particular to an improved semiconductor structure, which is suitable for wafer bonding and can improve wafer edge bonding defects.

### 2. Description of the Prior Art

Wafer bonding is a process for temporary or permanent joining of two or more wafers with or without an intermediate layer. During direct wafer bonding, how to increase the bonding strength is a concern.

There is a need in this technical field to provide an improved semiconductor structure to avoid the formation of edge bonding voids during the wafer bonding process. There remains a need in the art to provide an improved semiconductor structure to form more bonding and increase bonding strength during the wafer bonding process.

### SUMMARY OF THE INVENTION

It is one object of the present disclosure to provide an improved semiconductor structure and manufacturing method to solve the deficiencies or shortcomings of the prior art.

One aspect of the present disclosure provides a semiconductor structure including a semiconductor substrate; a dielectric structure disposed on the semiconductor substrate; a plurality of conductive pads disposed in the dielectric structure, wherein top surfaces of the plurality of conductive pads and a top surface of the dielectric structure collectively form a bonding interface; and a plurality of bonding-enhancement pads disposed in the dielectric structure and exposed at the bonding interface, wherein a material of the plurality of bonding-enhancement pads is different from a material of the dielectric structure and a material of the conductive pads.

According to some embodiments, the plurality of bonding-enhancement pads include a plurality of dangling bonds at the bonding interface.

According to some embodiments, the plurality of bonding-enhancement pads include a silicon-rich oxide layer.

According to some embodiments, the silicon-rich oxide layer includes a SiOCH layer.

According to some embodiments, a silicon atomic percentage in the silicon-rich oxide layer is greater than or equal to 30%.

According to some embodiments, the dielectric structure includes a cap layer, a top dielectric layer disposed on the cap layer, and a bonding dielectric layer disposed on the top dielectric layer.

According to some embodiments, the plurality of bonding-enhancement pads are disposed in the bonding dielectric layer and the top dielectric layer.

According to some embodiments, the plurality of bonding-enhancement pads do not penetrate the cap layer.

According to some embodiments, the plurality of conductive pads include copper pads, and the plurality of conductive pads penetrate the dielectric structure to be electrically connected to an interconnect structure disposed on the semiconductor substrate.

According to some embodiments, the semiconductor substrate includes a silicon-on-insulator (SOI) substrate, and the SOI substrate includes a base layer, a trap-rich layer, a buried oxide layer, and a device layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 7 are schematic diagrams of a method of manufacturing a semiconductor structure according to an embodiment of the present disclosure.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

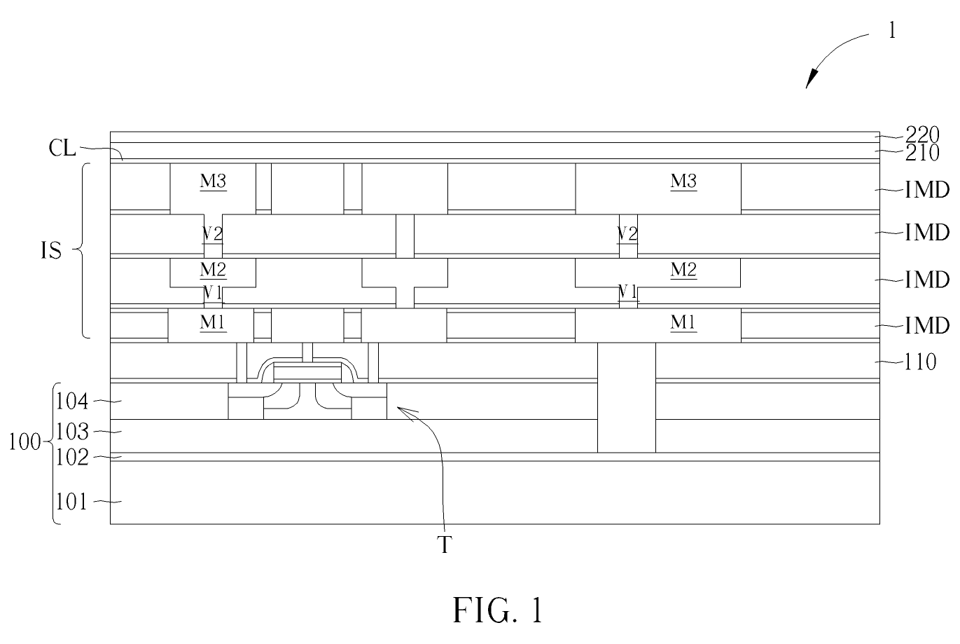

Please refer to FIGS. 1 to 7, which are schematic diagrams of a method of manufacturing a semiconductor structure 1 according to an embodiment of the present disclosure. As shown in FIG. 1, a semiconductor substrate 100, for example, a silicon-on-insulator (SOI) substrate is provided. According to an embodiment of the present disclosure, the semiconductor substrate 100 may include a base layer 101, a trap-rich layer 102 that is contiguous with the base layer 101, a buried oxide layer 103 that is contiguous with the trap-rich layer 102, and a device layer 104 that is contiguous with the buried oxide layer 103. According to an embodiment of the present disclosure, for example, the trap-rich layer 102 may include amorphous silicon or polycrystalline silicon.

According to an embodiment of the present disclosure, a circuit element T and a dielectric layer 110 covering the circuit element T may be formed on the device layer 104. According to an embodiment of the present disclosure, for example, the circuit element T may be a MOS transistor. According to an embodiment of the present disclosure, for example, the dielectric layer 110 may include an undoped silicate glass (USG) layer or a silicon oxide layer, but is not limited thereto.

After planarizing the dielectric layer 110, an interconnection structure IS is formed on the semiconductor substrate 100. According to an embodiment of the present disclosure, for example, the interconnect structure IS may include metal conductor layers M1-M3, via layers V1 and V2, and an inter-metal dielectric layer IMD. Those skilled in the art should understand that the interconnection structure IS in the figure is only for illustration.

Subsequently, a cap layer CL is formed on the interconnection structure IS. According to an embodiment of the present disclosure, for example, the cap layer CL may include nitrogen-doped silicon carbide, but is not limited thereto. A top dielectric layer 210 is then formed on the cap layer CL. According to an embodiment of the present disclosure, for example, the top dielectric layer 210 may include silicon oxide, but is not limited thereto. According to an embodiment of the present disclosure, the thickness of the top dielectric layer 210 is 9000-9500 angstroms.

Subsequently, a bonding dielectric layer 220 is formed on the top dielectric layer 210 for wafer bonding. According to an embodiment of the present disclosure, for example, the bonding dielectric layer 220 may include nitrogen-doped silicon carbide, but is not limited thereto. According to an embodiment of the present disclosure, the thickness of the bonding dielectric layer 220 is 1500-2100 angstroms.

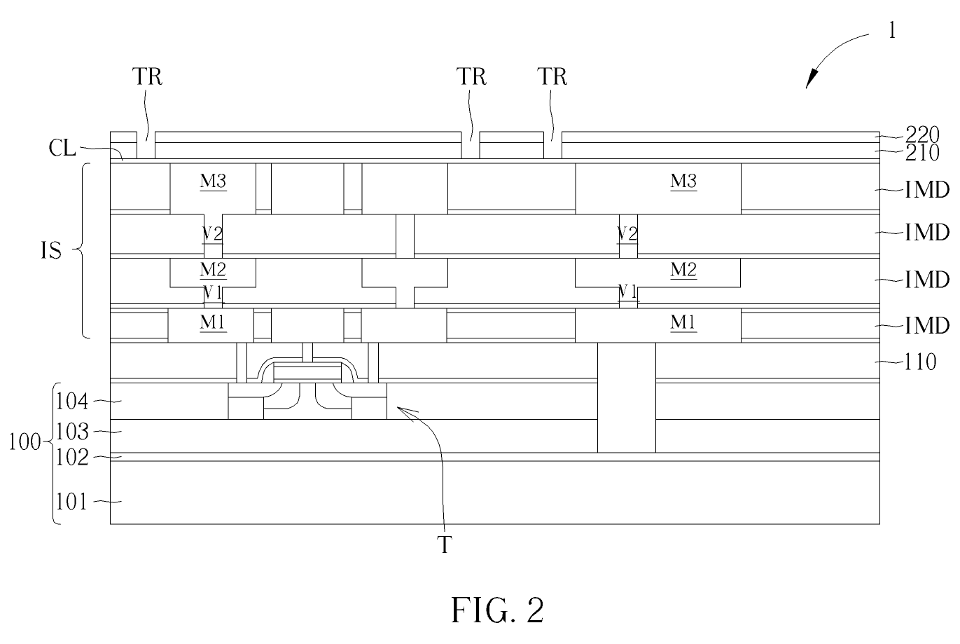

As shown in FIG. 2, a photolithography process and an etching process are then performed to form a trench TR in the bonding dielectric layer 220 and the top dielectric layer 210. According to an embodiment of the present disclosure, the trench TR does not overlap the underlying metal conductor layer M3. According to some embodiments of the present disclosure, the trench TR may overlap the underlying metal conductor layer M3. According to an embodiment of the present disclosure, the trench TR does not penetrate through the cap layer CL.

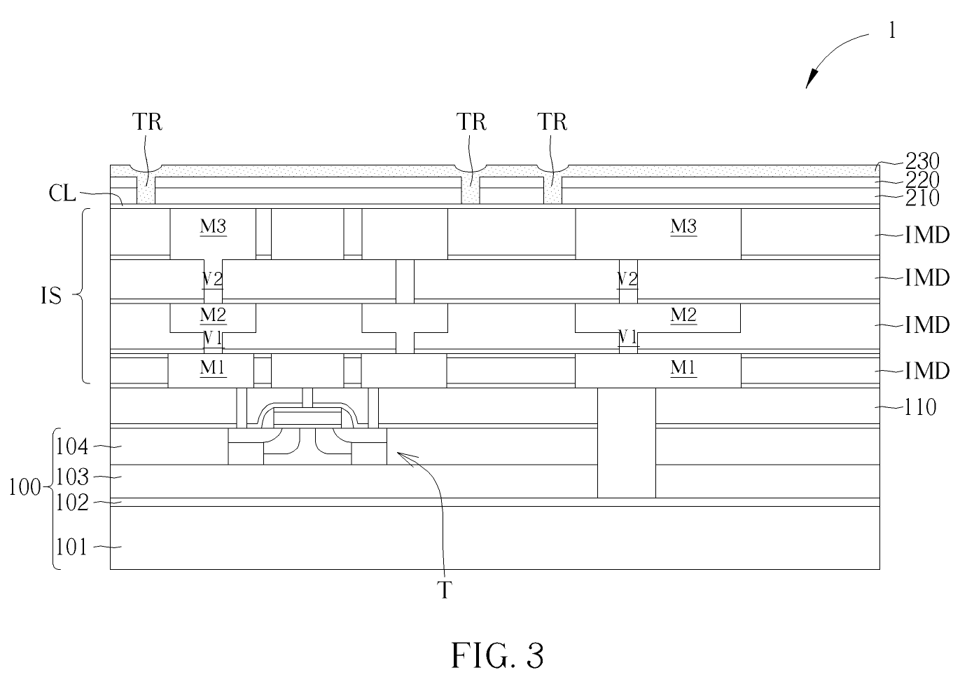

As shown in FIG. 3, a chemical vapor deposition (CVD) process is then performed to deposit a silicon-rich oxide layer 230, such as a SiOCH layer, on the semiconductor substrate 100 in a blanket manner. According to an embodiment of the present disclosure, for example, the atomic percentage of silicon in the silicon-rich oxide layer 230 is greater than or equal to 30%. At this point, the trench TR may be completely filled with the silicon-rich oxide layer 230.

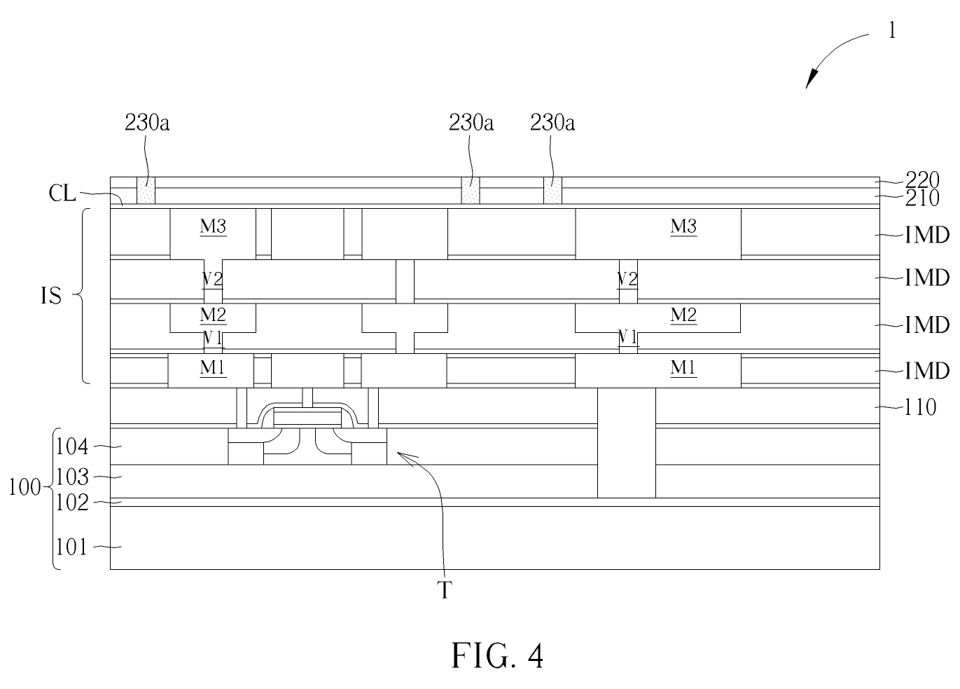

As shown in FIG. 4, a chemical mechanical polish (CMP) process is then performed to form a plurality of dangling-bond pads 230a(also referred to as bonding-enhancement pads in the claims) in the bonding dielectric layer 220 and the top dielectric layer 210. According to an embodiment of the present disclosure, the top surfaces of the plurality of dangling-bond pads 230a are coplanar with the top surface of the bonding dielectric layer 220. According to an embodiment of the present disclosure, a large number of dangling bonds is formed on the top surface of the dangling-bond pad 230a

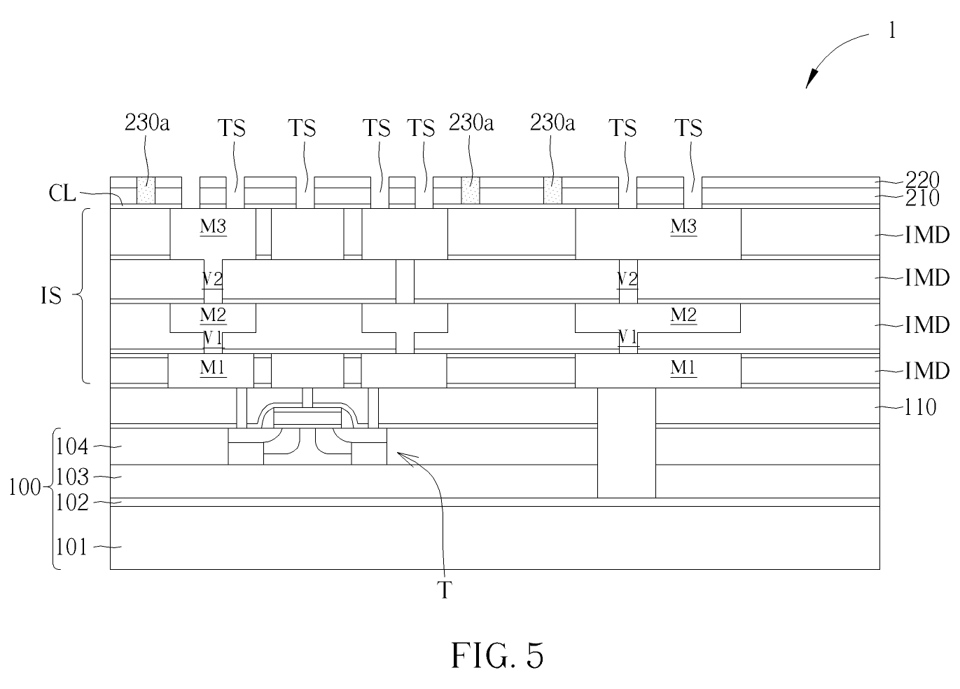

As shown in FIG. 5, a photolithography process and an etching process are then performed to form a trench TS in the bonding dielectric layer 220 and the top dielectric layer 210. According to an embodiment of the present disclosure, the trench TS overlaps the underlying metal conductor layer M3. According to an embodiment of the present disclosure, the trench TS penetrates the cap layer CL.

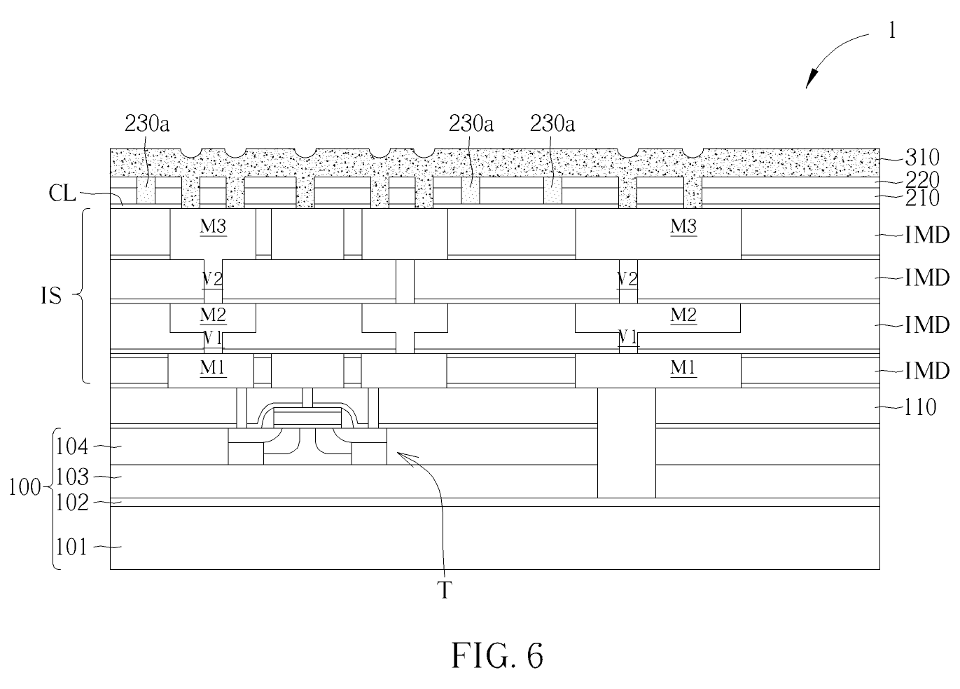

As shown in FIG. 6, a deposition process or an electroplating process is then performed to deposit a conductive layer 310, such as a copper metal layer, on the semiconductor substrate 100 in a blanket manner. At this point, the trench TS may be completely filled with the conductive layer 310.

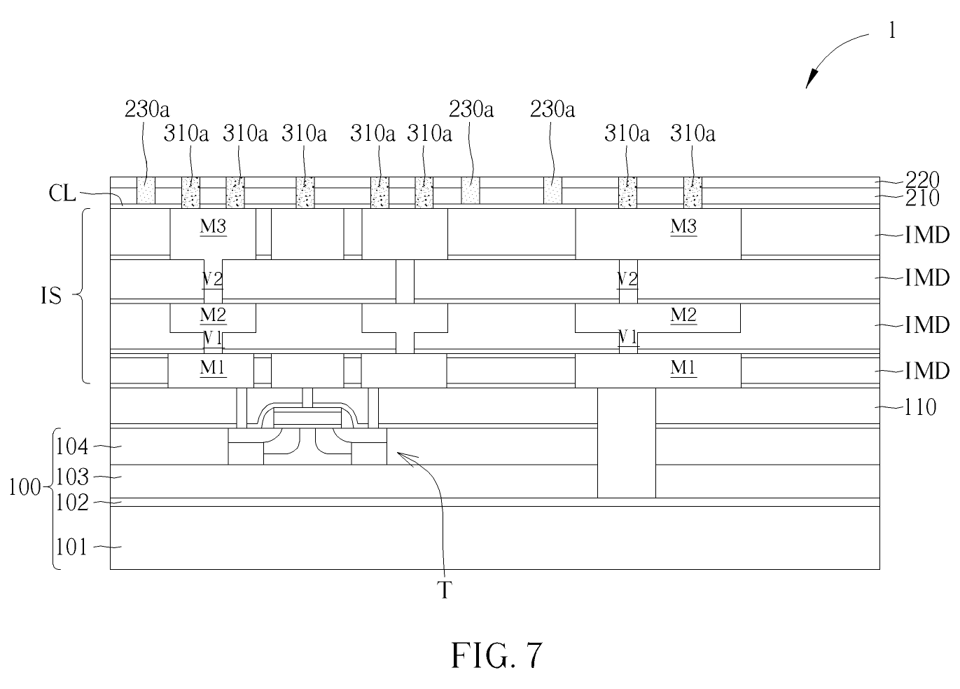

As shown in FIG. 7, a chemical mechanical polishing process is then performed to planarize the conductive layer 310, thereby forming a plurality of copper pads 310a in the bonding dielectric layer 220, the top dielectric layer 210 and the cap layer CL. According to an embodiment of the present disclosure, the plurality of copper pads 310a is used to form bonds with corresponding copper pads on another wafer (not shown), and the plurality of dangling-bond pads 230acan enhance the wafer bonding strength.

Structurally, as shown in FIG. 7, the semiconductor structure 1 of the present disclosure includes: a semiconductor substrate 100; an interconnection structure IS provided on the semiconductor substrate 100; a cap layer CL provided on the interconnection structure IS; a top dielectric layer 210 disposed on the cap layer CL; a bonding dielectric layer 220 disposed on the top dielectric layer 210; a plurality of copper pads 310a disposed in the bonding dielectric layer 220, the top dielectric layer 210 and the cap layer CL; and a plurality of dangling-bond pads 230a(bonding-enhancement pads) provided in the bonding dielectric layer 220 and the top dielectric layer 210.

According to an embodiment of the present disclosure, the plurality of dangling-bond pads 230amay include a silicon-rich oxide layer. According to an embodiment of the present disclosure, the plurality of dangling-bond pads 230amay include a SiOCH layer. According to an embodiment of the present disclosure, the plurality of dangling-bond pads 230adoes not penetrate through the cap layer CL.

According to an embodiment of the present disclosure, a top surface of the plurality of dangling-bond pads 230ais coplanar with a top surface of the plurality of copper pads 310a and a top surface of the bonding dielectric layer 220.

According to an embodiment of the present disclosure, the top dielectric layer 210 may include silicon oxide. According to an embodiment of the present disclosure, the thickness of the top dielectric layer 210 is 9000-9500 angstroms.

According to an embodiment of the present disclosure, the bonding dielectric layer 220 may include nitrogen-doped silicon carbide. According to an embodiment of the present disclosure, the thickness of the bonding dielectric layer 220 is 1500-2100 angstroms.

According to an embodiment of the present disclosure, the semiconductor substrate 100 may include a silicon-on-insulator (SOI) substrate.

The foregoing outlines the features of several embodiments, enabling those skilled in the art to fully appreciate the aspects of the present disclosure. Those skilled in the art should recognize that the present disclosure provides a foundation for designing or modifying other processes and structures to achieve substantially the same functions and/or substantially the same results as those of the embodiments introduced herein. Furthermore, such equivalent arrangements do not deviate from the spirit and scope of the present disclosure, and various changes, substitutions, and alterations may be made without so departing.

What is claimed is:

1. A semiconductor structure, comprising:
a semiconductor substrate;
a dielectric structure disposed on the semiconductor substrate;
a plurality of conductive pads disposed in the dielectric structure, wherein top surfaces of the plurality of conductive pads and a top surface of the dielectric structure collectively form a bonding interface; and
a plurality of bonding-enhancement pads disposed in the dielectric structure and exposed at the bonding interface, wherein a material of the plurality of bonding-enhancement pads is different from a material of the dielectric structure and a material of the conductive pads.

2. The semiconductor structure according to claim 1, wherein the plurality of bonding-enhancement pads comprise a plurality of dangling bonds at the bonding interface.

3. The semiconductor structure according to claim 1, wherein the plurality of bonding-enhancement pads comprise a silicon-rich oxide layer.

4. The semiconductor structure according to claim 3, wherein the silicon-rich oxide layer comprises a SiOCH layer.

5. The semiconductor structure according to claim 3, wherein a silicon atomic percentage in the silicon-rich oxide layer is greater than or equal to 30%.

6. The semiconductor structure according to claim 1, wherein the dielectric structure comprises a cap layer, a top dielectric layer disposed on the cap layer, and a bonding dielectric layer disposed on the top dielectric layer.

7. The semiconductor structure according to claim 6, wherein the plurality of bonding-enhancement pads are disposed in the bonding dielectric layer and the top dielectric layer.

8. The semiconductor structure according to claim 7, wherein the plurality of bonding-enhancement pads do not penetrate the cap layer.

9. The semiconductor structure according to claim 1, wherein the plurality of conductive pads comprise copper pads, and the plurality of conductive pads penetrate the dielectric structure to be electrically connected to an interconnect structure disposed on the semiconductor substrate.

10. The semiconductor structure according to claim 1, wherein the semiconductor substrate comprises a silicon-on-insulator (SOI) substrate, and wherein the SOI substrate comprises a base layer, a trap-rich layer, a buried oxide layer, and a device layer.
